(19) United States
(12) Patent Application Publication
(10) Pub. No.: US 2026/0163567 A1
(43) Pub. Date: Jun. 11, 2026

(54) POWER-ON RESET CIRCUITS WITH BROWNOUT DETECTION

(71) Applicant: Nuvoton Technology Corporation, Hsinchu (TW)

(72) Inventor: Bal S. Sandhu, Fremont, CA (US)

(21) Appl. No.: 18/974,635

(22) Filed: Dec. 9, 2024

(51) Int. Cl. H03K 17/22

(52) U.S. Cl. CPC H03K 17/223

(57) ABSTRACT

Power-on reset (POR) circuits with brownout detection, including small form factor and/or low-power/low-voltage POR circuits, are disclosed herein. In one embodiment, a POR circuit includes at least one current mirror and an inverter having an input coupled to the at least one current mirror. A voltage at the input of the inverter is based at least in part on (i) a current produced by the at least one current mirror and (ii) a power supply voltage. The POR circuit is configured to generate a power-on reset bar signal based at least in part on the output of the inverter. In some embodiments, the POR circuit can further include a Schmitt-trigger buffer coupled to the output of the inverter to provide hysteresis to the power-on reset bar signal.

### TECHNICAL FIELD

This disclosure relates generally to power management circuits for integrated circuits. For example, several embodiments of the present technology are directed to power-on reset circuits with brownout detection, and to associated systems, devices, and methods.

### BACKGROUND

Power-on reset (POR) circuits are commonly employed in integrated circuits and other electronic systems. These circuits ensure that when power is initially applied to a system, internal registers and components are initialized to a known state before normal operation begins. Such initialization is crucial for achieving correct functionality and preventing unpredictable behavior.

In many electronic systems, particularly those powered by batteries or subject to fluctuating power supplies, it is important to maintain proper operation not only during initial power-up but also during periods of low voltage conditions. These low voltage conditions, often referred to as brownouts, can occur when the power supply voltage drops below a certain threshold but does not completely fail.

### BRIEF DESCRIPTION OF FIGURES

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 is a circuit schematic illustrating a power-on reset circuit configured in accordance with various embodiments of the present technology.

FIG. 2 is a plot illustrating output voltage versus input voltage for an inverter of the power-on reset circuit in accordance with various embodiments of the present technology.

FIG. 3 is a plot showing voltage behavior of a power-on reset circuit of the present technology over time in accordance with various embodiments of the present technology.

### DETAILED DESCRIPTION

The present disclosure is generally directed to power-on reset (POR) circuits for integrated circuits and other electronic devices, and to associated systems, devices, and methods. The POR circuits disclosed herein are configured to hold corresponding integrated circuits and other electronic devices in reset until a supply voltage is ramped to a threshold voltage level, thereby ensuring proper initialization of registers and/or other components of the integrated circuits/electronic devices during powerup after power is first applied/supplied. POR circuits of the present technology may also include brownout detection capabilities for indicating when the supply voltage drops too low during operation. The POR circuits of the present technology are expected to consume little power and take up minimal space on a chip, making them particularly useful in battery-powered devices where conserving power and/or detecting low battery conditions are important.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. OVERVIEW

Power-on reset (POR) circuits are commonly used in integrated circuits and electronic systems to hold such integrated circuits and electronic systems in reset during powerup until a power supply voltage V_{DD} reaches a predefined voltage level V_{POR}, thereby (a) ensuring proper initialization of internal registers and components as the integrated circuits and electronic systems are permitted to come out of reset and (b) increasing the likelihood that the integrated circuits and electronic systems function as intended. The predefined voltage level V_{POR} (also referred to herein as the “reset voltage level” or the “trigger voltage level”) is carefully chosen to be above a minimum operating voltage of system components (e.g., above threshold voltages of NMOS transistors) but below the full operating voltage (e.g., less than a difference between the nominal supply voltage and threshold voltages of PMOS transistors). In many cases, the predefined voltage level V_{POR} is set to around half of the nominal (or full-scale) supply voltage V_{DD_FS}.

Many POR circuits utilize bandgap circuits. While such POR circuits can provide stable trigger voltages V_{POR}, they often consume significant power, require substantial chip area, and are relatively complex to implement. Other POR circuits utilize delay-generation-based circuits. Such circuits, however, can be sensitive to variations in temperature and power supply rise time, and may require large passive components to achieve suitable delay characteristics. For example, if a rise time of a power supply voltage V_{DD} is large compared to an RC delay in the delay-generation-based circuit, the corresponding integrated circuit or other electronic system may be permitted to come out of reset too early. Additionally, such circuits may require large RC components to achieve a decent time constant for the rise time of the power supply voltage V_{DD}, meaning that such circuits often occupy a large amount of chip area.

As electronic devices continue to shrink in size, there is a growing need for POR circuits with smaller footprints. In addition, there is a need for low-power POR circuits, especially for applications involving battery-powered devices (e.g., mobile or wearable devices). Furthermore, the ability to detect and respond to brownout conditions—where the supply voltage drops below a certain threshold but does not completely fail—is becoming increasingly important, especially in battery-powered, mobile phone, and/or wearable electronics applications.

POR circuits configured in accordance with various embodiments of the present technology are expected to address one or more of these needs while avoiding many of the issues discussed above with reference to other POR circuit solutions. For example, POR circuits configured in accordance with various embodiments of the present technology can utilize a multi-stage design comprising current mirrors and one or more inverters to generate a power-on reset bar signal PORB. More specifically, several POR circuits of the present technology can include a first stage that utilizes first and second current mirrors for bias current generation, and a second stage with a third current mirror and an inverter for triggering the power-on reset bar reset signal PORB once a power supply voltage V_{DD} has ramped to a preset voltage level VPOR. In some embodiments, POR circuits of the present technology can additionally include a third stage comprising a Schmitt trigger buffer for providing hysteresis.

Such multi-stage designs have a smaller footprint and consume a lower amount power in comparison to the other POR circuit solutions discussed above, making these POR circuits particularly suitable for smaller and/or battery-powered devices. In addition, as discussed in greater detail below, trip points of these POR circuits can be set by ratios of currents in the various stages, providing stability across temperature variations and independence from power supply rise time, enabling their reliable use in various applications such as mobile phones, wearable electronics, industrial control systems, and automotive electronics, among other applications. Furthermore, many of these POR circuits include integrated brownout detection capabilities that allow the circuits to respond to low-voltage conditions during operation, enhancing reliability in battery-powered systems and/or systems with fluctuating power supplies. In other words, POR circuits configured in accordance with various embodiments of the present technology offer various combinations of features that make these POR circuits particularly well-suited for use in mobile phones, wearable technology, and other compact electronic devices where power efficiency and reliable operation are critical.

### B. SELECTED EMBODIMENTS OF POWER-ON RESET CIRCUITS WITH BROWNOUT DETECTION, AND ASSOCIATED SYSTEMS, DEVICES, AND METHODS

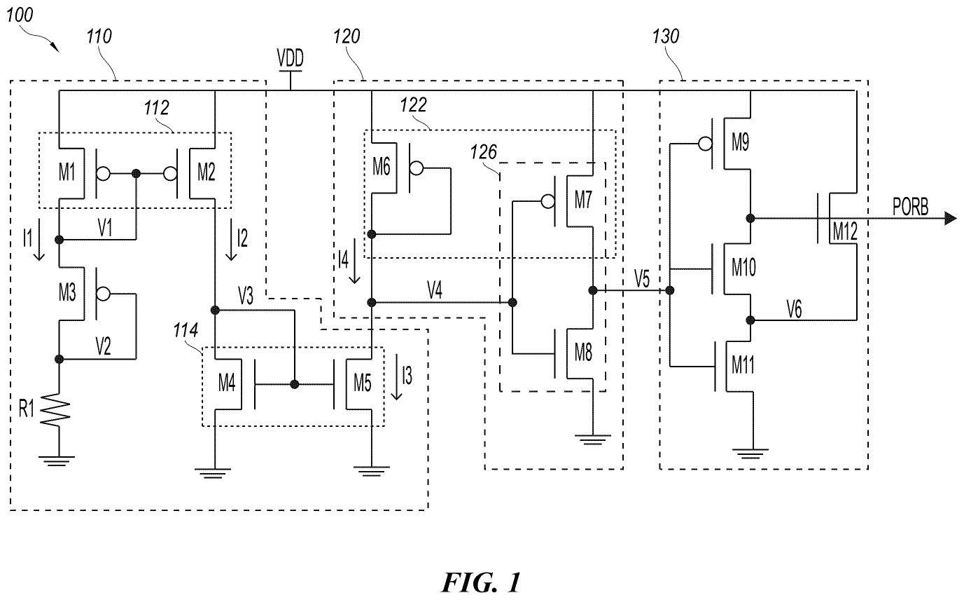

FIG. 1 is a circuit schematic illustrating a power-on reset (POR) circuit 100 configured in accordance with various embodiments of the present technology. As shown, the POR circuit 100 includes a first stage 110, a second stage 120, and an optional third stage 130. The first stage 110 can be a current generation stage, the second stage 120 can be a trip (or trigger) voltage generation stage, and the third stage 130 can be an output stage including a Schmitt-trigger buffer for providing hysteresis.

In the illustrated embodiment, the first stage 110 includes a first current mirror 112 formed by transistors M1 and M2, a second current mirror 114 formed by transistors M4 and M5, a transistor M3, and a resistor R1. The first current mirror 112 is shown as a PFET current mirror in which the transistors M1 and M2 are PMOS transistors. The gates of the transistors M1 and M2 are coupled to one another, and the sources of the transistors M1 and M2 are coupled to a power supply voltage V_{DD}. A drain of the transistor M2 is coupled to the second current mirror 114, and a drain of the transistor M1 is coupled to a source of the transistor M3. The transistor M3 is illustrated as a PMOS transistor. Both the transistor M1 and the transistor M3 are diode-connected transistors, each having its gate coupled to its drain. The resistor R1 is coupled between the transistor M3 and ground.

The second current mirror 114 is illustrated as an NFET current mirror in which the transistors M4 and M5 are NMOS transistors. The gates of the transistors M4 and M5 are coupled to one another, and the sources of the transistors M4 and M5 are coupled to ground. The transistor M4 is illustrated as a diode-connected transistor, having its gate coupled to its drain. The drain of the transistor M4 is further coupled to the drain of the transistor M2, and a drain of the transistor M5 is coupled to node V4 and the second stage 120.

In operation, the first stage 110 is configured to generate a first current I1 at the drain of the transistor M1 based at least in part on the transistor M1, the transistor M3, the resistor R1, and the power supply voltage V_{DD}. More specifically, the transistor M1, the transistor M3, and the resistor R1 generate a bias voltage at node V1 based on the power supply voltage V_{DD}, which is transduced by the transistor M1 into the first current I1. As shown, the transistors M1 and M3 are diode-connected PMOS transistors. Thus, the first stage 110 is configured to generate the first current I1 when the power supply voltage V_{DD} is at a voltage level that is sufficient to produce voltages at nodes V1 and V2 that enable current to conduct through channels of the transistors M1 and M2, respectively, based on threshold voltages of the transistors M1 and M2. This configuration is expected to ensure that the power supply voltage V_{DD} reaches a sufficient level before an inverter 126 in the second stage 120 can be triggered and a power-on reset bar signal PORB output from the POR circuit 100 can be asserted (e.g., activated, transitioned to an “on” state, transitioned to a high state).

The first current mirror 112 generates a second current I2 at the drain of the transistor M2 based at least in part on the first current I1. For example, the transistor M4 of the second current mirror 114 is a diode-connected NMOS transistor. Thus, the current mirror 112 can generate the second current I2 when the power supply voltage V_{DD} is at a voltage level sufficient enough that voltage at node V3 enables current to conduct through a channel of the transistor M4 based on the threshold voltage of the transistor M4, which should occur whenever the first stage 110 generates the first current I1 given the arrangement of the transistors M1 and M3. The second current I2 is also referred to herein as an “intermediate current,” a “mirrored current,” and the like.

Assuming that the transistors M1 and M2 have the same size and process characteristics, the second current I2 generated at the drain of the transistor M2 can be equivalent to the first current I1 generated at the drain of the transistor M1. The transistors M1, M2 of the first current mirror 112 both operate in saturation. Thus, the first current I1 and the second current I2 can be represented by Equation 1 below in which p is carrier mobility, Cₒₓ is gate oxide capacitance per unit area, W₁ is channel width, L₁ is channel length, V_{GS1} is gate-to-source voltage, and V_{T1} is threshold voltage for the PMOS transistors M1 and M2 of the first current mirror 112:

$${I}_{1} = {I}_{2} = \frac{{μ}_{P} {C}_{O X}}{2} ( \frac{{W}_{1}}{{L}_{1}} ) {( {V}_{G S 1} - {V}_{T 1} )}^{2} \qquad Equation 1$$

Referring now to the second current mirror 114, the second current mirror 114 generates a third current I3 at the drain of the transistor M5 based on the second current I2. The third current I3 is also referred to herein as a “mirrored current” and the like. Assuming that the transistors M4 and M5 have the same size and process characteristics, the third current I3 generated at the drain of the transistor M5 can be equivalent to the second current I2 generated at the drain of the transistor M4. The transistors M4, M5 of the second current mirror 114 both operate in saturation. Thus, the second current I2 and the third current I3 can be represented by Equation 2 below in which μ_{N} is carrier mobility, Cₒₓ is gate oxide capacitance per unit area, W₂ is channel width, L₂ is channel length, V_{GS2} is gate-to-source voltage, and V_{T2} is threshold voltage for the NMOS transistors M4 and M5 of the second current mirror 114:

$${I}_{2} = {I}_{3} = \frac{{μ}_{N} {C}_{O X}}{2} ( \frac{{W}_{2}}{{L}_{2}} ) {( {V}_{G S 2} - {V}_{T 2} )}^{2} \qquad Equation 2$$

Equation 1 and Equation 2 above demonstrate that the first current I1, the second current I2, and the third current I3 are each dependent upon the threshold voltages of the transistors M1, M2, M4, and M5. As a result, as discussed in greater detail below, the first and second current mirrors 112, 114 can be complementary to one another and be used to track threshold voltage variations of the transistors M1, M2, M4, and M5 (e.g., induced by temperature changes).

In some embodiments, the POR circuit 100 can be configured as a low-voltage POR circuit. For example, characteristics of the resistor R1 and/or the transistors M1, M2, M3, M4, and/or M5 can be chosen/designed such that the first stage 110 targets a first current I1 of approximately 100 nanoamperes (nA), which is mirrored to the second current I2 and the third current I3. Such a low current level for the first current I1, the second current I2, and the third current I3 is expected to reduce direct current (DC) power and assist with operating the first current mirror 112 and the second current mirror 114 in a weak inversion region by keeping gate-to-source voltages V_{GS} of the transistors M1, M2, M4, and/or M5 less than or equal to respective threshold voltages. In turn, operation of the first current mirror 112 and the second current mirror 114 in the weak inversion region is expected to lower static and dynamic power dissipation, which is especially beneficial for mobile and other battery-powered applications.

In some embodiments, the resistor R1 of the first stage 110 may be implemented as a variable resistor. For example, the resistor R1 may include multiple resistor segments with metal or register options to short out one or more of the segments. Such a configuration may allow (a) for adjustment of the bias voltage generated at the node V1 and/or (b) for adjustment of the first current I1 generated at the drain of the transistor M1. In some embodiments, the ability to adjust the resistance of the resistor R1 may provide a means to compensate for process variations or to fine-tune the trip point of the POR circuit 100.

Referring now to the second stage 120 of the POR circuit 100, the second stage 120 includes a transistor M6 and an inverter 126 formed by transistors M7 and M8. The transistor M6 is illustrated as a diode-connected PMOS transistor, having its gate coupled to its drain. A source of the transistor M6 is coupled to the power supply voltage V_{DD}, and the gate and the drain of the transistor M6 are coupled, via the node V4, to (i) the drain of the transistor M5 and (ii) the gates of the transistors M7, M8. The transistor M6 serves as an active load and forms a current mirror 122 with the transistor M7.

The transistor M7 is illustrated as a PMOS transistor, and the transistor M8 is illustrated as an NMOS transistor. The gates of the transistors M7, M8 are coupled (i) to one another and (ii) to the drains of the transistors M5 and M6 via node V4. The transistor M7 further includes a source coupled to the power supply voltage V_{DD}, and a drain coupled, via node V5, to (i) a drain of the transistor M8 and (ii) an input of the third stage 130. The transistor M8 further includes a source coupled to ground.

In operation, the second stage 120 is configured to generate a fourth current I4 at the drain of the transistor M6. A voltage at the node V4 depends on the difference between the fourth current I4 and the third current I3, and is used to trip the inverter 126 when (i) the power supply voltage V_{DD} is rising and the voltage at node V4 rises to a trigger voltage level and (ii) the power supply voltage V_{DD} is falling and the voltage at node V4 falls to the trigger voltage level.

The trigger voltage level is a characteristic of the inverter 126 and is set at a value that is equal to or greater than a threshold voltage of the transistor M8. In some embodiments, the trigger voltage level represents a midpoint voltage V_{M} of the inverter 126 that occurs when the voltage at node V4 (representing an input voltage V_{IN} at the input of the inverter 126) is equivalent to the voltage at node V5 (representing an output voltage V_{OUT} at the output of the inverter 126). In these and other embodiments, the trigger voltage level can be or correspond to approximately half a full-scale power supply voltage V_{DD_FS} (e.g., V_{DD_FS}/2).

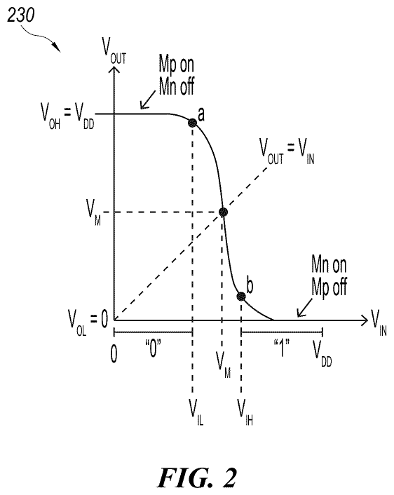

As a specific example, consider FIG. 2 that illustrates a plot 230 showing voltage characteristics of the inverter 126 of the second stage 120 of the POR circuit 100 of FIG. 1. The plot 230 shows a relationship between input voltage V_{IN} and output voltage V_{OUT} of the inverter 126. More specifically, the input voltage V_{IN} corresponds to the voltage at the node V4 in FIG. 1 that is applied to the gates of transistors M7 and M8 of FIG. 1, and the output voltage V_{OUT} corresponds to the voltage observed at node V5 that represents the output of the inverter 126 and the output of the second stage 120 of FIG. 1.

As shown in the plot 230, for input voltages between 0V and a voltage input low (V_{IL}) value, the output voltage V_{OUT} remains at a high level, approximately equal to the power supply voltage V_{DD}. More specifically, when the input voltage V_{IN} is between 0V and V_{IL}, the PMOS transistor M7 of the inverter 126 is on (activated) while the NMOS transistor M8 of the inverter 126 is off (deactivated). As a result, the output voltage V_{OUT} is roughly equivalent to a voltage level of the power supply voltage V_{DD}, or an output high voltage V_{OH}. Voltage values between 0V and V_{IL} value for the input voltage V_{IN} correspond to a logic level “0.”

As the input voltage V_{IN} increases beyond V_{IL}, the output voltage V_{OUT} begins to decrease. The rate of decrease becomes steeper as V_{IN} approaches the mid-point voltage V_{M}. The midpoint voltage V_{M} occurs when the input voltage V_{IN} is equal to the output voltage V_{OUT}. This point represents the trip point of the inverter 126, at which the inverter 126 changes states. As shown, the midpoint voltage V_{M} is approximately equal to half the power supply voltage V_{DD} (e.g., V_{DD}/2).

For input voltages between a voltage input high (V_{IH}) value and the power supply voltage V_{DD}, the output voltage V_{OUT} remains at a low level, approximately equal to 0V. More specifically, when the input voltage V_{IN} is between V_{IH} and the power supply voltage V_{DD}, the PMOS transistor M7 of the inverter 126 is off (deactivated) while the NMOS transistor M8 of the inverter 126 is on (activated). As a result, the output voltage V_{OUT} is roughly equivalent to 0V, or an output low voltage V_{OL}. Voltage values between V_{IH} and the power supply voltage V_{DD} for the input voltage V_{IN} correspond to logic level “1.”

At the trigger voltage level, the transistors M7 and M8 of the inverter 126 of FIG. 1 operate in saturation, and it is assumed that current through the transistor M7 is equivalent to current through the transistor M8 when voltage at node V4 is equivalent to the midpoint voltage V_{M}. Thus, the midpoint voltage V_{M} (representing the trip point of the inverter 126) may be mathematically determined. More specifically, the current through the transistors M7 and M8 at the midpoint voltage V_{M} can be represented by Equation 3 below in which P and N are carrier mobilities, C_{OXP} and C_{OXN} are gate oxide capacitances per unit area, W_{P} and W_{N} are channel widths, L_{P} and L_{N} are channel lengths, V_{TP} and V_{TN} are threshold voltages for the inverter 126, and V_{M} is the midpoint voltage:

$${I}_{M7} = \frac{{μ}_{P} {C}_{O X P}}{2} ( \frac{{W}_{P}}{{L}_{P}} ) {( {V}_{D D} - {V}_{M} - \vert {V}_{T P} \vert )}^{2} = \frac{{β}_{P}}{2} {( {V}_{D D} - {V}_{M} - \vert {V}_{T P} \vert )}^{2} = {I}_{M 8} = \frac{{μ}_{N} {C}_{O X N}}{2} ( \frac{{W}_{N}}{{L}_{N}} ) {( {V}_{M} - {V}_{T N} )}^{2} = \frac{{β}_{N}}{2} {( {V}_{M} - {V}_{T N} )}^{2} \qquad Equation 3$$

Equating current I_{M7} through the transistor M7 with current I_{M8} through the transistor M8, rearranging the equation, and solving for the midpoint voltage V_{M} (as shown below) therefore leads to Equation 4 below for the midpoint voltage V_{M}:

$$\begin{matrix}Equating currents through M 7 and M 8 : \\ {\frac{{β}_{N}}{2} {( {V}_{M} - {V}_{T N} )}^{2} = \frac{{β}_{P}}{2} {V}_{D D} - {V}_{M} - \vert {V}_{T P} \vert )}^{2} \\ Rearranging equation : \\ \sqrt{\frac{{β}_{N}}{{β}_{P}} {( {V}_{M} - {V}_{T N} )}^{2}} = {V}_{D D} - {V}_{M} - \vert {V}_{T P} \vert\end{matrix}$$

$${V}_{M} = \frac{{V}_{D D} - \vert {V}_{T P} \vert + {V}_{T N} \sqrt{\frac{{β}_{N}}{{β}_{P}}}}{1 + \sqrt{\frac{{β}_{N}}{{β}_{P}}}} = \frac{{V}_{D D} - \vert {V}_{T P} \vert + {V}_{T N} \sqrt{\frac{{μ}_{N} {C}_{O X N} ( \frac{{W}_{N}}{{L}_{N}} )}{{μ}_{P} {C}_{O X N} ( \frac{{W}_{P}}{{L}_{P}} )}}}{1 + \sqrt{\frac{{μ}_{N} {C}_{O X N} ( \frac{{W}_{N}}{{L}_{N}} )}{{μ}_{P} {C}_{O X N} ( \frac{{W}_{P}}{{L}_{P}} )}}} \qquad Equation 4$$

Equation 4 above demonstrates that the midpoint voltage V_{M} (representing the trigger voltage or trip point of the inverter 126) is set by a ratio of currents; is independent of rise time of the power supply voltage V_{DD}; and is a function of the device sizes (channel widths W and channel lengths L of the transistors M7 and M8), the threshold voltages V_{TP} and V_{TN} of the transistors M7 and M8, and the power supply voltage V_{DD}. Threshold voltages V_{TP} and V_{TN} of the transistors M7 and M8 are proportional to the ratio of channel length L to channel width W. Hence, assuming channel width W remains constant, a longer transistor channel leads to a higher threshold voltage. Therefore, in some embodiments, the channel lengths for transistors of the POR circuit 100 (e.g., for one or more of the transistors M1-M8) can be chosen to be larger (e.g., three times or more) than the corresponding channel widths. In addition, as discussed above, the midpoint voltage V_{M} is also a function of the power supply voltage V_{DD}. As such, the midpoint voltage V_{M} (representing the trip point of the inverter 126) will be lower for smaller power supply voltages V_{DD}. As such, characteristics (e.g. channel width W and/or channel length L) of the transistors M7 and M8 of the inverter 126 can be chosen to account for the power supply voltage V_{DD} and for the threshold voltages of the transistors M7 and M8.

The POR circuit 100 is configured such that the voltage at node V4 does not reach the midpoint (or trigger) voltage V_{M} until the power supply voltage V_{DD} reaches a sufficient level. More specifically, as discussed above, the first current I1, the second current I2, and the third current I3 are not reliably generated until the power supply voltage V_{DD} has reached a level in which PMOS transistors M1 and M2 of the first current mirror 112 and the NMOS transistors M4 and M5 of the second current mirror 114 are activated and conducting.

In addition, as discussed above, the first current mirror 112 and the second current mirror 114 of the first stage 110 of the POR circuit 100 of FIG. 1 are complementary to one another and operate to track threshold voltage variations of the transistors M1, M2, M4 and M5 (e.g., due to process differences and/or changes in temperature over time). For example, as the threshold voltages of the transistor M1 and the transistor M2 rise (e.g., due to temperature changes), the bias voltage generated at node V1 increases. In turn, the first current I1 generated at the drain of the transistor M1, the second current I2 generated at the drains of the transistors M2 and M4, the third current I3 generated at the drain of the transistor M5, and the fourth current I4 generated at the drain of the transistor M6 each decrease. As a result, in comparison to the scenario in which the threshold voltages of the transistors M1 and M2 do not increase, the POR circuit 100 will require the power supply voltage V_{DD} to reach a higher voltage level to charge the voltage at node V4 at the input of the inverter 126 to the trigger voltage V_{M}. The POR circuit 100 operates in a similar fashion when the threshold voltages of the transistors M4 and M5 increase.

As another example, as the threshold voltages of the transistor M1 and the transistor M2 decrease, the bias voltage generated at node V1 decreases. In turn, the first current I1, the second current I2, the third current I3, and the fourth current I4 each increase. As a result, in comparison to the scenario in which the threshold voltages of the transistors M1 and M2 do not decrease, the POR circuit 100 will require the power supply voltage V_{DD} to reach a lower voltage level to charge the voltage at node V4 at the input of the inverter 126 to the trigger voltage V_{M}. The POR circuit 100 operates in a similar fashion when the threshold voltages of the transistors M4 and M5 decrease.

Referring now to the third stage 130 of the POR circuit 100, the third stage 130 includes a Schmitt-trigger buffer that provides hysteresis to the POR circuit 100. In the illustrated embodiment, the Schmitt-trigger buffer includes transistors M9, M10, M11, and M12. The transistor M9 is shown as a PMOS transistor having a source coupled to the power supply voltage V_{DD} and to a drain of the transistor M12, a drain coupled to a drain of the transistor M10 and to a gate of the transistor M12, and a gate coupled to gates of the transistors M10 and M11. The transistors M10, M11, and M12 are illustrated as NMOS transistors. The transistor M11 further includes (i) a source coupled to ground and (ii) a drain coupled, via node V6, to a source of the transistor M10 and a source of the transistor M12. The third stage 130 and the Schmitt-trigger buffer are illustrated with an input at node V5 that is coupled to the gates of the transistors M9, M10, and M11. The third stage 130 and the Schmitt-trigger buffer are further illustrated with an output at the gate of the transistor M12 between the drain of the transistor M9 and the drain of the transistor M10. The output of the third stage 130 and the Schmitt-trigger buffer correspond to an output of the POR circuit 100.

As discussed above, the Schmitt-trigger buffer is configured to add hysteresis to the POR circuit 100 (e.g., to the trigger voltage V_{M} of the inverter 126). It is expected that such hysteresis reduces the likelihood of the POR circuit 100 being falsely triggered in the event of noise or a glitch while the power supply voltage V_{DD} is ramping up toward the full-scale power supply voltage V_{DD_FS}. More specifically, the Schmitt-trigger buffer may provide hysteresis by adding extra current into a leg of the buffer at node V6. For example, transistor M10 is connected in a feedback path that extends from the source of the transistor M10, through the transistor M12, and to the power supply voltage V_{DD}. Thus, while the power supply voltage V_{DD} rises, the voltages at node V4 (corresponding to the input of the inverter 126), node V5 (corresponding to the output of the inverter 126 and to the input of the Schmitt-trigger buffer and the third stage 130), and the output of the POR circuit 100 increase. In turn, additional charge is injected at node V6 through the transistor M12 due to the increased voltage at the gate of the transistor M12, which raises the voltage at node V6. This increase in voltage at node V6 increases the threshold voltage of the transistor M10, thereby delaying the trip point of the POR circuit 100 and ensuring that the voltage at node V5 has gone sufficiently beyond the threshold voltage of the transistor M9 before triggering and bringing the POR circuit 100 out of reset (e.g., by asserting the power-on reset bar signal PORB). The Schmitt-trigger buffer similarly provides hysteresis when the power supply voltage V_{DD} is ramping downward, as discussed in greater detail below.

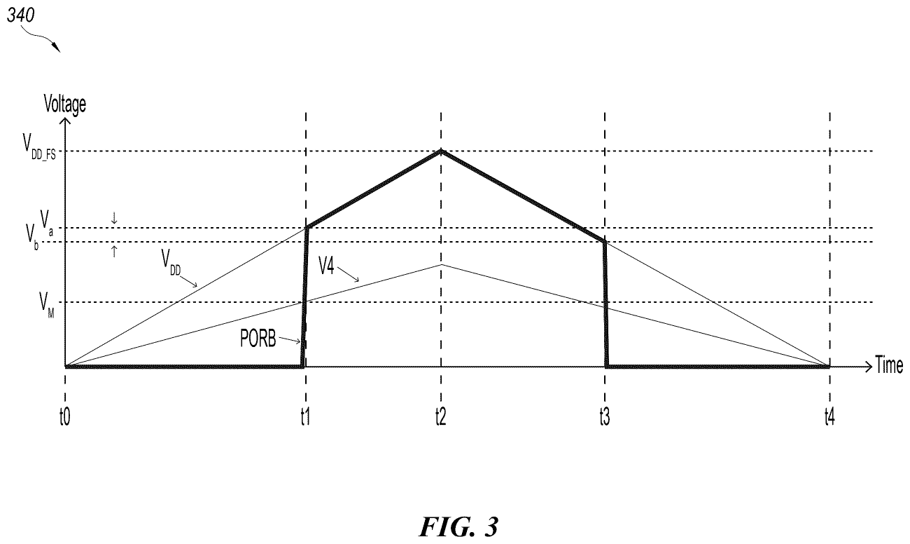

FIG. 3 is a plot 340 illustrating the behavior of the POR circuit 100 over time in accordance with various embodiments of the present technology. The plot shows voltage on the vertical axis and time on the horizontal axis, with specific time points labeled as t0, t1, t2, t3, and t4. Hysteresis provided by the Schmitt-trigger buffer is represented in the plot 340 by a voltage difference Va-Vb. As discussed above, such hysteresis helps prevent false triggering due to noise or glitches in the power supply voltage V_{DD} and/or the voltage at node V4 (corresponding to the input of the inverter 126 of FIG. 1).

At time t0, the power supply voltage V_{DD} begins to ramp up from 0V. As shown, while the power supply voltage V_{DD} is ramping between time t0 and time t1, the voltage on node V4 (corresponding to the input of the inverter 126 of FIG. 1) also slowly increases. Despite the increase in the power supply voltage V_{DD} and the voltage at node V4 during this period, the power-on reset bar PORB signal remains low (keeping the corresponding electronic system in reset) because the voltage at node V4 has not yet reached the trigger voltage V_{M} that trips the inverter 126 to activate the transistor M8 and deactivate the transistor M7.

Shortly before time t1, the voltage on node V4 reaches the trigger voltage V_{M}. As shown, this occurs when the power supply voltage V_{DD} has risen to about half of its full-scale voltage V_{DD_FS}. At this point, the power-on reset signal PORB remains unasserted due to hysteresis introduced by the Schmitt-trigger buffer in the third stage 130 of the POR circuit 100.

At time t1, the power supply voltage V_{DD} has risen to a voltage level Va such that the voltage at node V4 (corresponding to the input of the inverter 126 of FIG. 1) has risen to a level that accounts for the hysteresis introduced by the Schmitt-trigger buffer. Thus, at this time, the power-on reset bar signal PORB switches high and matches the voltage level of the power supply voltage V_{DD}, thereby bring the corresponding electronic system out of reset.

Between time t1 and t2, the power-on reset signal PORB follows the power supply level V_{DD} as the power supply level V_{DD} continues to rise. The voltage at node V4 also continues to increase during this period. At time t2, the power supply voltage V_{DD} reaches its full-scale voltage level V_{DD_FS}.

Between time t2 and time t3, the power supply voltage V_{DD} is illustrated as ramping downward toward 0V. During this period, the power-on reset bar signal PORB remains asserted but tracks the decreasing power supply voltage V_{DD}. The voltage on node V4 also ramps downward during this period, following the decreasing power supply voltage V_{DD}.

Shortly before time t3, the voltage at node V4 (corresponding to the input of the inverter 126 of FIG. 1) reaches the trigger voltage V_{M}, which trips the inverter 126 to deactivate the transistor M8 and activate the transistor M7. As shown, this occurs when the power supply voltage V_{DD} has fallen to about half of its full-scale voltage V_{DD_FS}. At this point, the power-on reset signal PORB remains asserted due to hysteresis provided by the Schmitt-trigger buffer in the third stage 130 of the POR circuit 100.

At time t3, the power supply voltage V_{DD} has fallen to a voltage level V_{b} such that the voltage at node V4 (corresponding to the input of the inverter 126 of FIG. 1) has fallen to a level that accounts for the hysteresis provided by the Schmitt-trigger buffer. Thus, at this time, the power-on reset bar signal PORB switches low to 0V (or ground), thereby bringing the corresponding electronic system back into reset. This transition indicates a brownout condition, where the supply voltage has dropped below a safe operating level. Brownout detection functionality of the POR circuit 100 is discussed in greater detail below.

As shown in the plot 340 of FIG. 3, as the power supply voltage V_{DD} continues to fall between time t3 and time t4, the power-on reset bar signal remains low. The voltage at node V4 continues to follow the falling power supply voltage V_{DD} during this time.

Were the power supply voltage V_{DD} to ramp toward its full scale voltage V_{DD_FS} during a time period following time t4, the behavior of the voltages observed at node V4 and the power-reset bar signal PORB would match that shown in the plot 340 of FIG. 340, demonstrating that the trigger voltage V_{M} and the corresponding trip point of the POR circuit 100 (accounting for hysteresis provided by the Schmitt-trigger buffer) remains constant across power cycling and/or when cycling the power supply V_{DD} low to high and/or high to low multiple times. Such consistency in the trigger voltage V_{M} and the trip point of the POR circuit 100 is expected to ensure reliable operation of the POR circuit 100 across varying power supply conditions.

Additionally, or alternatively, were the power supply voltage V_{DD} to plateau, fall, and/or rise at a different rate between time t0 and time t1 shown in the plot 340, the power-on reset bar signal PORB would still be asserted whenever the power supply voltage V_{DD} reaches the voltage level Va. Similarly, were the power supply voltage V_{DD} to plateau, rise, and/or fall at a different rate between time t2 and time t3 shown in the plot 340, the power-on reset bar signal PORB would be de-asserted whenever the power supply voltage V_{DD} falls to the voltage level V_{b}. As such, the trip point of the POR circuit 100 of FIG. 1 is independent of the rise time or the fall time of the power supply voltage V_{DD}.

As discussed above, the POR circuit 100 can provide brownout detection functionality. More specifically, as the power supply voltage V_{DD} falls to a voltage level at which the voltage at node V4 is below the trigger voltage V_{M} of the inverter 126 by an amount that accounts for hysteresis provided by the Schmitt-trigger buffer of the third stage 130, the power-on reset bar signal PORB can be de-asserted. This is shown at time t3 in the plot 340 of FIG. 3, where the power supply voltage V_{DD} has fallen the voltage level V_{b}. De-assertion of the power-on reset bar signal PORB can be used as an indication of a brownout condition. For example, the de-assertion of the power-on reset bar signal PORB (e.g., outside of a power-down operation or a reset operation of the corresponding electronic system) may be used as a warning signal to initiate data backup procedures before the power supply voltage V_{DD} drops to levels where register states might be lost. Hysteresis provided by the Schmitt-trigger buffer may help prevent false triggers due to small fluctuations in the power supply voltage V_{DD}, enhancing the reliability of the brownout detection.

In some embodiments, in response to the brownout indication provided by de-assertion of the power-on reset bar signal PORB, a corresponding electronic system can save critical data to non-volatile memory, complete one or more ongoing operations, prepare for an orderly shutdown, and/or activate backup power sources (if available). In other words, the brownout detection capability of the POR circuit 100 can enable corresponding electronic systems to implement proactive measures to preserve data integrity in the event of brownout conditions, thereby increasing the likelihood of smooth recovery when power is restored. In some embodiments, the trigger voltage V_{M} and/or the voltage level V_{b} at which the power-on reset bar signal PORB de-asserts may be chosen to be sufficiently above a minimum operating voltage of corresponding system components. This selection may provide an adequate window of time for the system to respond to the brownout warning before reaching a critical low-voltage state where register contents or other volatile information might be compromised.

The brownout detection functionality of the POR circuit 100 described above may be particularly useful in battery-powered devices, systems subject to unreliable power sources, or applications where data integrity is crucial. By providing early warning of decreasing supply voltage, the POR circuit 100 may enable more robust and reliable operation across a wide range of power conditions.

Although shown with a third stage 130 and corresponding Schmitt-trigger buffer in FIG. 1, the POR circuit 100 in other embodiments of the present technology can omit the third stage 130 and the corresponding Schmitt-trigger buffer. For example, in lieu of the third stage 130 and the Scmitt-trigger buffer, the POR circuit 100 can employ a large capacitor on the power supply. In such embodiments, the power-on reset bar signal can be (a) asserted when the power supply voltage V_{DD} is rising and the voltage at node V4 reaches the trigger voltage V_{M}, and (b) de-asserted when the power supply voltage V_{DD} is falling the voltage at node V4 falls to the trigger voltage V_{M}. Additionally, or alternatively, although the first current mirror 112 is shown as PFET current mirror and the second current mirror 114 is shown as an NFET current mirror in FIG. 1, the first current mirror 112 and the second current mirror 114 of the POR circuit 100 can be an NFET current mirror and a PFET current mirror in other embodiments of the present technology.

### C. CONCLUSION

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A power-on reset (POR) circuit, comprising:
at least one current mirror; and
an inverter having an input coupled to the at least one current mirror,
wherein:
a voltage at the input of the inverter is based at least in part on (i) a current produced by the at least one current mirror and (ii) a power supply voltage, and
the POR circuit is configured to generate a power-on reset bar signal based at least in part on an output of the inverter.

2. The POR circuit of claim 1, wherein the at least one current mirror includes a PFET current mirror.

3. The POR circuit of claim 2, wherein the at least one current mirror further includes an NFET current mirror coupled to the PFET current mirror.

4. The POR circuit of claim 1, wherein:
the at least one current mirror includes a current mirror having a first transistor and a second transistor;
the first transistor is a diode-connected transistor that is coupled between the power supply voltage and ground;
the POR circuit further comprises a third transistor; and
the third transistor is a diode-connected transistor that is coupled between the first transistor and ground.

5. The POR circuit of claim 1, wherein:
the at least one current mirror includes a current mirror having a first transistor and a second transistor;
the first transistor is a diode-connected transistor that is coupled between the power supply voltage and ground;
the POR circuit further comprises a resistor; and
the resistor is coupled between the first transistor and ground.

6. The POR circuit of claim 5, wherein the resistor includes a variable resistor.

7. The POR circuit of claim 1, wherein:
the at least one current mirror includes a current mirror having a first transistor and a second transistor;
the first transistor is a diode-connected transistor;
the first transistor and the second transistor are each coupled between the power supply voltage and ground;
the POR circuit further comprises a third transistor coupled between the power supply voltage and the second transistor; and
the third transistor is a diode-connected transistor and is configured as an active load.

8. The POR circuit of claim 1, further comprising a Schmitt-trigger buffer coupled to the output of the inverter and configured to provide hysteresis to the power-on reset bar signal.

9. A power-on reset (POR) circuit, comprising:
a bias generation stage configured to generate a bias current based at least in part on a power supply voltage;
a trip point generation stage coupled to the bias generation stage and configured to generate a voltage at a node based at least in part on the bias current; and
an output stage coupled to the trip point generation stage and configured to generate a power-on reset bar signal based at least in part on the voltage at the node.

10. The POR circuit of claim 9, wherein the bias generation stage comprises:
a first current mirror configured to generate the bias current; and
a second current mirror coupled to the first current mirror and configured to mirror the bias current to the trip point generation stage.

11. The POR circuit of claim 9, wherein the trip point generation stage comprises an inverter, and wherein the voltage at the node is applied to an input of the inverter.

12. The POR circuit of claim 9, wherein the output stage comprises a Schmitt trigger buffer, and wherein the Schmitt trigger buffer is configured to:
assert the power-on reset bar signal when the power supply voltage rises above a first threshold; and
de-assert the power-on reset bar signal when the power supply voltage falls below a second threshold that is lower than the first threshold.

13. A method of operating a power-on reset (POR) circuit, the method comprising:
generating a current based at least in part on a power supply voltage;
mirroring the generated current across one or more current mirrors; and
tripping an inverter based at least in part on the generated current and the power supply voltage.

14. The method of claim 13, wherein tripping the inverter includes:
as the power supply voltage is rising, tripping the inverter when a voltage at an input of the inverter reaches a trigger voltage of the inverter; or
as the power supply voltage is falling, tripping the inverter when the voltage at the input of the inverter drops to the trigger voltage of the inverter.

15. The method of claim 14, further comprising asserting, based at least in part on the tripping of the inverter, a power-on reset bar signal after accounting for hysteresis.

16. The method of claim 14, further comprising de-asserting, based at least in part on the tripping of the inverter, a power-on reset bar signal after accounting for hysteresis.

17. The method of claim 14, wherein tripping the inverter as the power supply voltage is rising comprises tripping the inverter when the power supply voltage reaches approximately half of a full-scale power supply voltage.

18. The method of claim 13, wherein generating the current comprises generating a current of approximately 100 nanoamperes.

19. The method of claim 13, wherein mirroring the generated current comprises operating at least one of the one or more current mirrors in a weak inversion region.

20. The method of claim 13, wherein mirroring the generated current includes (a) mirroring the generated current across a first current mirror to produce an intermediate current and (b) mirroring the intermediate current across a second current mirror different from the first current mirror to produce mirrored current, and wherein tripping the inverter based at least in part on the generated current includes tripping the inverter based at least in part on the mirrored current.
